(19) United States
(12) Patent Application Publication
(10) Pub. No.: US 2026/0198047 A1
(43) Pub. Date: Jul. 9, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventor: Wei-Chih WEN, Hsinchu (TW)

(73) Assignee: Taiwan Semiconductor Manufacturing Company, Ltd., Hsinchu (TW)

(21) Appl. No.: 19/009,180

(22) Filed: Jan. 3, 2025

(51) Int. Cl. H10D 30/67; H10D 1/00; H10D 30/01; H10D 64/68

(52) U.S. Cl. CPC H10D 30/6737; H10D 1/041; H10D 30/0312; H10D 64/691; H10D 64/693

(57) ABSTRACT

A method for manufacturing a semiconductor device is provided. The manufacturing method includes the following steps. A bottom gate electrode is formed, and the bottom gate electrode has a base electrode and a metal layer disposed on top of the base electrode. A gate insulating layer is formed on the bottom gate electrode. An active layer is formed on the gate insulating layer. A dielectric layer is formed on the active layer, wherein the dielectric layer is partially etched to form at least two vias, and the two vias expose a portion of the active layer. A source electrode and a drain electrode are formed into the two vias respectively for electrically connecting the active layer.

### BACKGROUND

Conventional manufacturing method of a semiconductor device generates contact regions of source and drain electrodes of a thin film transistor (TFT) by chemical vapor deposition (CVD) or physical vapor deposition (PVD). While back-end-of-line (BEOL) device is scaling down with short channel length (less than 50 nm) and reducing thickness (less than 10 nm), oxide semiconductor field effect transistors (OSFET) would suffer severe short channel effect (SCE) even by dual-layer channel stacking. In addition, such oxygen-related defects in OSFET also deteriorate the stability of threshold voltage (Vt), and will result in a decrease in the reliability of the thin film transistor, and thus it needs to have further improvements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a bottom gate electrode according to an embodiment of the present disclosure.

FIGS. 2A and 2B are schematic cross-section view and top view of a semiconductor device according to an embodiment of the present disclosure.

FIGS. 3 to 7 are schematic diagrams illustrating a method for manufacturing a semiconductor device according to an embodiment of the present disclosure.

FIGS. 8 to 11 are schematic diagrams illustrating a method for manufacturing a MIM capacitor according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

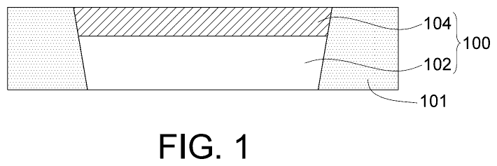

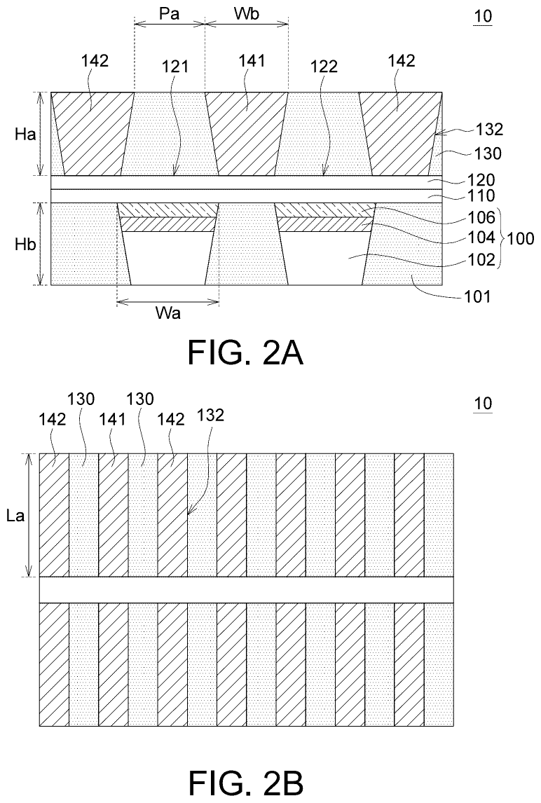

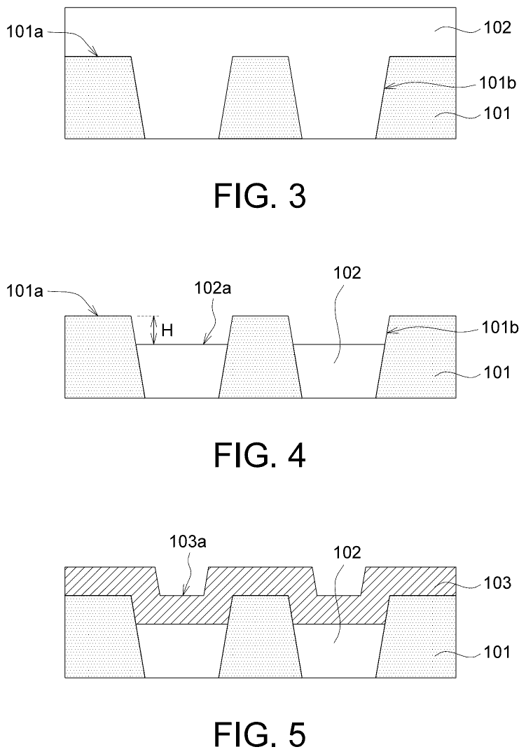

Please refer to FIGS. 1, 2A and 2B. FIG. 1 is a schematic diagram of a bottom gate electrode 100 according to an embodiment of the present disclosure. FIGS. 2A and 2B are schematic cross-section view and top view of a semiconductor device 10 according to an embodiment of the present disclosure. Although these embodiments take the thin film transistor having the bottom gate electrode 100 as an example, the present disclosure is not limited thereto, and can also be implemented by other embodiments. The semiconductor device 10 of FIG. 2A can be formed by the manufacturing method shown in FIGS. 3 to 7.

In FIG. 2A, the semiconductor device 10 includes a bottom gate electrode 100, a gate insulating layer 110, an active layer 120, a dielectric layer 130, a source electrode 141 and two drain electrodes 142. The gate insulating layer 110 is disposed between the bottom gate electrode 100 and the active layer 120. The dielectric layer 130 is disposed on the top of the active layer 120. The source electrode 141 and the drain electrodes 142 pass through the dielectric layer 130 and are electrically connected to the active layer 120 to form a first channel region 121 between the source electrode 141 and one of the drain electrodes 142 and a second channel region 122 between the source electrode 141 and the other one of the drain electrodes 142. The source electrode 141 is used to a common source for the two drain electrodes 142. The bottom gate electrode 100 includes a first gate electrode corresponding to control the first channel region 121 and a second gate electrode corresponding to control the second channel region 122. In other embodiments, the bottom gate electrode 100 of FIG. 1 is illustrated by only one, and the bottom gate electrode 100 is disposed to control the first channel region 121 and the second channel region 122.

Although the bottom gate electrode 100 of FIG. 2A are illustrated by two gate electrodes, the quantity of the bottom gate electrodes 100 is not limited. In FIG. 2B, there are plenty of source electrodes 141 and drain electrodes 142 alternately arranged on the plane, and the pitch Pa from one edge of the source electrodes 141 to one edge of the adjacent drain electrode 142 may be between about 15 nm and about 1000 nm. The width Wa of the bottom gate electrode 100 may be equal to or greater than the pitch Pa. The width Wb of the source electrodes 141 and the drain electrodes 142 may be greater than 20 nm. The length La of the source electrodes 141 and the drain electrodes 142 of FIG. 2B may be between about 50 nm and about 500 nm. The thickness Ha of the bottom gate electrode 100 and the thicknesses Hb of the source electrodes 141 and the drain electrode 142 may be between 20 nm and about 50 nm. The thickness of the gate insulating layer 110 may be between about 2 nm and about 12 nm, and the thickness of the active layer 120 may be between about 5 nm and about 12 nm.

The material of the bottom gate electrode 100 includes a metal layer 104 formed on a base electrode 102. The metal layer 104 includes titanium (Ti), tungsten (W), niobium (Nb), molybdenum (Mo), vanadium (V), cobalt (Co), chromium (Cr), nickel (Ni) or a combination thereof. In some embodiments, the material of the base electrode 102 includes metal nitride, such as titanium nitride (TiN), tungsten nitride (WN), niobium nitride (NbN), molybdenum nitride (MoN), vanadium nitride (VN), cobalt nitride (CoN), chromium nitride (CrN), nickel nitride (Ni₃N) and the like, but the disclosure is not limited thereto.

In FIG. 1, the metal layer 104 of the bottom gate electrode 100 can avoid metal nitride oxidation to generate nitrogen in the interface between the base electrode 102 and the gate insulating layer 110. The generated nitrogen causes reliability issues during field stress. As shown in FIG. 2A, when the gate insulating layer 110 is formed on the top of the bottom gate electrode 100, the metal layer 104 reacts with oxygen to form a metal oxide (such as titanium oxide) 106 instead of forming metal oxynitride (such as TiON). The metal oxide 106 can prevent metal oxynitride (such as TiON) from being generated between the base electrode 102 and the gate insulating layer 110 to improve reliability of the bottom gate electrode 100.

The gate insulating layer 110 is formed on the top of the bottom gate electrode 100. The gate insulating layer 110 may be a dielectric material including silicon oxide (SiOx), aluminum oxide (AlOx), hafnium oxide: zirconium oxide (HfOx: ZrOx), hafnium oxide: aluminum oxide (HfOx: AlOx), hafnium oxide: oxide Lanthanum (HfOx: LaOx), hafnium oxide: silicon oxide (HfOx: SiOx), hafnium oxide: strontium oxide (HfOx: SrO), hafnium zirconium oxide (HZO) doped with cerium oxide (CeOx), etc.

One common gate insulating layer 110 is silicon oxide. While a thinner silicon oxide gate dielectric is also more susceptible to tunneling and has a greater gate leakage. In addition, high-k dielectric materials used as the gate insulating layer 110 have been introduced into field effect transistors (FETs) for better transistor performance and the demand of low operation voltage. The high-k dielectric materials may be hafnium oxide (HfOx), hafnium zirconium oxide (HZO) or other dielectrics with a dielectric constant more than 6. While any suitable gate dielectric material may be used, some examples of the present disclosure use a high-k dielectric material as the gate insulating layer 110 to reduce leakage current, reduce threshold voltage, and/or optimize the operation of the transistor.

The active layer 120 is formed on the top of the gate insulating layer 110, and the material of the active layer 120 includes monocrystalline silicon (a-Si), polycrystalline silicon (poly-Si) or oxide semiconductor.

In some embodiments, the metal oxynitride semiconductor comprises at least one of In, Ga, and Zn. Other elements can be selected among Ti, Al, W, Ce, Sn, Zr, Nd, Sm and Lu for addition formation element of metal oxynitride semiconductor.

FIGS. 3 to 7 are schematic diagrams illustrating a method for manufacturing the semiconductor device 10 according to an embodiment of the present disclosure. The method for manufacturing the semiconductor device 10 includes the following steps. Referring to FIGS. 3 to 6, a bottom gate electrode 100 is formed. The bottom gate electrode 100 may be a laminated gate electrode including multiple layers (i.e., a base electrode 102 and a metal layer 104), and the thickness of the bottom gate electrode 100 may be about 20 nm to 50 nm. For example, in the formation process of the base electrode 102, the base electrode 102 is formed in an opening 101b of a dielectric layer 101 by CVD, PVD or ALD, and the side edge of the base electrode 102 is protruded over the top surface 101a of the dielectric layer 101. The base electrode 102 is made of metal nitride, such as titanium nitride (TiN), tungsten nitride (WN), niobium nitride (NbN), molybdenum nitride (MoN), vanadium nitride (VN), cobalt nitride (CoN), chromium nitride (CrN), nickel nitride (Ni₃N) and the like. The specific material(s) used depend upon the desired work function of the gate and the type of semiconductor devices.

In FIG. 4, the base electrode 102 is etched back so that the top surface 102a of the base electrode 102 is lower than the top surface 101a of the dielectric layer 101. The height difference H between the top surface 101a of the dielectric layer 101 and the top surface 102a of the base electrode 102 depends on the thickness of a metal layer 104 to be deposited on the top surface 102a of the base electrode 102. For example, the thickness of the metal layer 104 to be deposited is about 10 Å to 20 Å.

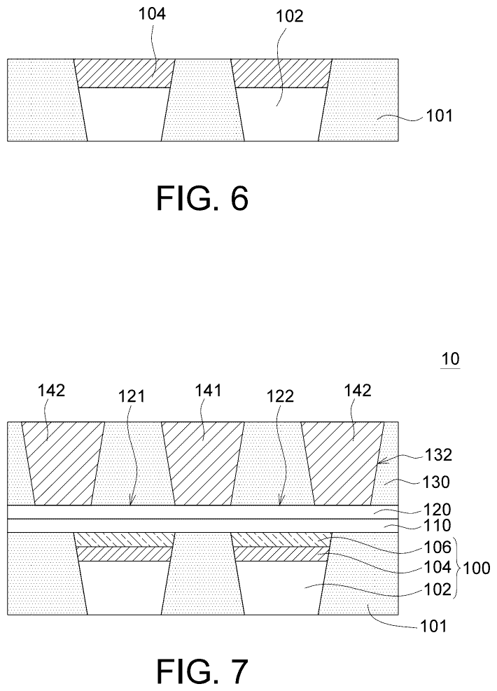

In FIG. 5, a metal material 103 is formed on the top surface 101a of the dielectric layer 101, the sidewall of the opening 101b and the top surface 102a of the base electrode 102 by CVD, PVD or ALD. That is, the metal material 103 has a concave portion 103a in the opening 101b of the dielectric layer 101. Next, in FIG. 6, the metal material 103 is removed by chemical mechanical polishing (CMP) except the concave portion 103a in the opening 101b of the dielectric layer 101 so as to form a metal layer 104 on the top surface 102a of the base electrode 102. The material of the metal layer 104 includes titanium (Ti), tungsten (W), niobium (Nb), molybdenum (Mo), vanadium (V), cobalt (Co), chromium (Cr), nickel (Ni) or a combination thereof. For example, when titanium nitride (TiN) is selected as the base electrode 102, titanium (Ti) can be used as the metal layer 104 to have good adhesion to the base electrode 102; when tungsten nitride (WN) is selected as the base electrode 102, tungsten (W) can be used as the metal layer 104 to have good adhesion to the base electrode 102, and so on.

In FIG. 7, a gate insulating layer 110 is formed on the bottom gate electrode 100. In the formation of the gate insulating layer 110, oxides such as HfOx or HZO can be selectively used. The multilayer insulating film can increase the dielectric constant. Therefore, the total film thickness of the multilayer gate insulating layer 110 can be reduced. In FIG. 7, although the gate insulating layer 110 is shown as a single layer, the gate insulating layer 110 may include multiple insulating layers, and each insulating layer may include a different dielectric material.

In FIG. 7, an active layer 120 is formed on the gate insulating layer 110. The sidewalls of the gate insulating layer 110 may be substantially flush with sidewalls of the active layer 120. Alternatively, the sidewalls of the gate insulating layer 110 may be not flush with the sidewalls of the active layer 120. The active layer 120 is, for example, a semiconductor or oxide-semiconductor, which can be formed by, for example, direct current (DC) sputtering or radio frequency (RF) sputtering. In the DC sputtering or RF sputtering, a sputtering target having the same composition as the oxide semiconductor of the active layer 120. Alternatively, the active layer 120 may be formed by a co-sputtering method using a plurality of sputtering targets (i.e., targets with Ar/O₂/N₂ gas flow, N at 1-10%), CVD, ALD (with NH₃ gas precursor), or PVD.

Referring to FIG. 7, in one embodiment, the active layer 120 is oxidized or annealed, for example, oxygen is introduced or N₂O treatment is performed at a Celsius temperature between 150 degrees and 350 degrees. N₂O plasma treatment can form an oxygen-rich, low carrier concentration interface layer at the interface, which can effectively repair oxide-semiconductor being damaged and resist the influence of passivation layer deposition. After N₂O plasma treatment, the proportion of oxygen vacancies in the film decreased, indicating that the oxygen vacancy concentration in the film decreased to a certain extent. Since oxygen vacancies in metal oxide semiconductors are a major source of carriers, the carrier concentration in the film will be reduced to a certain extent.

In some embodiments, other oxides, for example, zinc oxide (ZnO), gallium oxide (GaO), indium oxide (InO), and nickel oxide (NiO) can be selectively used as a capping layer (not shown) to cover the active layer 120, the capping layer has high bonding force with oxygen ions and can prevent oxygen ions from being bombarded by plasma and released (i.e., bond breaking). The thickness of the capping layer may be between 10 Å and 200 Å, but it is not limited in the present disclosure.

In FIG. 7, a dielectric layer 130 is formed on the active layer 120 and surrounds the top surface and sidewalls of the active layer 120. The dielectric layer 130 may be SiOx, SiON, SiN, low-k dielectrics or the like. The dielectric layer 130 is formed by, for example, CVD, ALD or PVD.

Referring to FIG. 7, the dielectric layer 130 is partially etched by plasma to form a plurality of vias 132 or trenches (see top view in FIG. 2B), and the vias 132 or trenches expose a portion of the active layer 120. The exposed portion of the active layer 120 serves as contact surfaces for connecting a source electrode 141 and two drain electrodes 142 subsequently deposited therein (see FIG. 7).

Referring to FIG. 7, the source electrode 141 and the drain electrodes 142 are formed in the vias 132 by CVD-ALD or PVD. A first channel region 121 is formed between the source electrode 141 and one of the drain electrodes 142, a second channel region 122 is formed between the source electrode 141 and the other one of the drain electrodes 142, and the gate electrode 100 is disposed under the first and second channel regions 121 and 122 for applying a gate voltage to control the currents respectively flowing through the first and second channel regions 121 and 122. The types of the source electrode 141 and the drain electrodes 142 are not particularly limited, and common electrode materials can be used. For example, the source electrode 141 and the drain electrodes 142 may be made by one of TaN, TiN, Molybdenum (Mo), Tungsten (W), Titanium (Ti) and the like or alloys.

The formation method of the source electrode 141 and the drain electrodes 142 is not limited, for example, a metal film is formed by a magnetron sputtering method or a radio frequency (RF) sputtering method, and then a wet etching is performed with an etchant of hydrogen peroxide, phosphoric acid, nitric acid or acetic acid to remove a portion of the metal film above the dielectric layer 130, thereby forming the source electrode 141 and the drain electrodes 142.

Please refer to FIG. 7, when the gate insulating layer 110 is formed on the top of the bottom gate electrode 100, the metal layer 104 reacts with oxygen to form metal oxide (such as titanium oxide) 106, instead of forming metal oxynitride (such as TiON), the metal oxide 106 can prevent metal oxynitride (such as TiON) from being generated between the base electrode 102 and the gate insulating layer 110 to improve reliability of the bottom gate electrode 100.

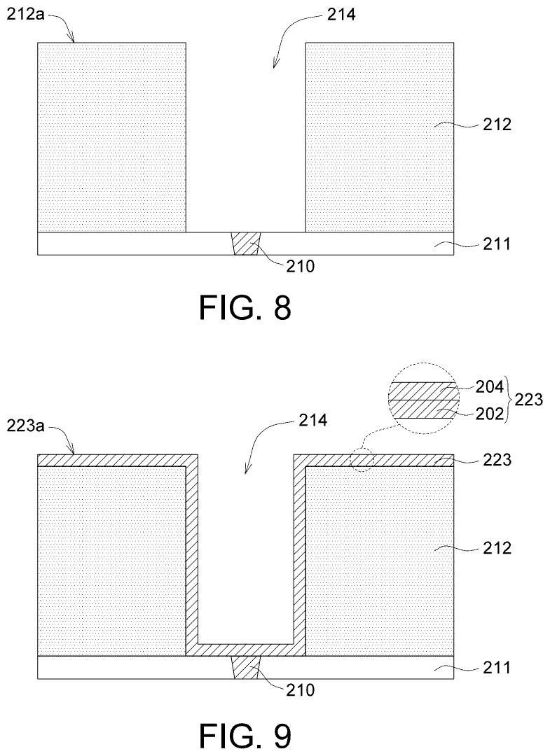

FIGS. 8 to 11 are schematic diagrams illustrating a method for manufacturing a MIM capacitor 20 according to an embodiment of the present disclosure. The present disclosure provides various embodiments of a three-dimensional (3D) MIM structure and methods of forming the same. In some embodiments, 3D MIM structures are provided in a back-end-of-line (BEOL) of semiconductor devices, where various components in a substrate are interconnected with metallization structures and via structures in corresponding dielectric layers. This approach allows the construction of 3D MIM capacitors between multiple deep via structures in BEOL.

Referring to FIG. 11, the MIM capacitor 20 includes a conductive metal layer 210 and a metal-insulator-metal (MIM) structure 220. The conductive metal layer 210 is disposed on a substrate 211. The MIM structure 220 is disposed on a patterned interlayer dielectric layer 212, the patterned interlayer dielectric layer 212 covers the substrate 211, and the patterned interlayer dielectric layer 212 has a plurality of trenches 214, and the conductive metal layer 210 is exposed at the bottom of the trenches 214. In one embodiments, the trenches 214 may be vias or the likes. The MIM structure 220 includes an upper electrode layer 221, an insulating layer 222 and a lower electrode layer 223. The insulating layer 222 is located between the upper electrode layer 221 and the lower electrode layer 223, wherein the lower electrode layer 223 covers the sidewalls and bottoms of the trenches 214, and the lower electrode layer 223 is electrically connected to the conductive metal layer 210. The upper electrode layer 221 and the lower electrode layer 223 are electrically insulated from each other to form a MIM structure 220.

The MIM capacitor 20 can be formed by various processes including deposition a dielectric layer using PVD, CVD and the like, photolithography and a dry/wet etching process. The thickness of this MIM capacitor 20 is controlled by the desired capacitance value, which is a function of the area of the metallization layers and the dielectric constant of the dielectric material of the MIM capacitor 20. In some embodiments, the thickness of each of the electrode layers of the MIM capacitor 20 can be in a range of a few tens of nanometers to a few hundreds of nanometers, e.g., 20-70 nanometers, and the thickness of the high dielectric constant material can be in a range of 3-8 nanometers.

In FIG. 8, an interlayer dielectric (ILD) layer 212 is deposited on a substrate 211 and formed on a conductive metal layer 210. A portion of the ILD layer 212 not covered by a patterned photoresist layer is etched to form a trench 214, and the conductive metal layer 210 is exposed from the bottom of the trench 214. In some embodiments, the number of trench 214 may be two or more, such as 4 to 16, arranged in a straight line or in an array. In one embodiment, only one trench 214 is shown as an example.

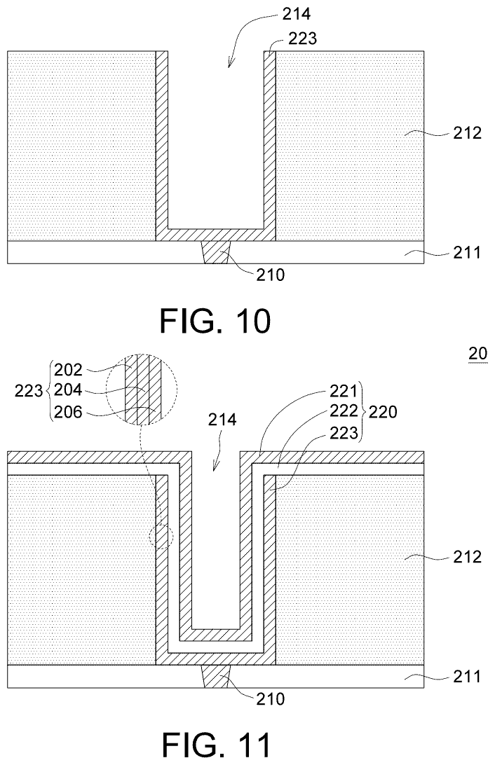

In FIG. 9, a lower electrode layer 223 is formed over the ILD layer 212 and in the trenches 214 by CVD, PVD or ALD. The lower electrode layer 223 covers the sidewalls and bottoms of the trenches 214. In FIG. 10, the top portion 223a of the lower electrode layer 223 covering the top surface 212a of the ILD layer 212 is removed by etching. After that, the insulating layer 222 and the upper electrode layer 221 are formed over the lower electrode layer 223, where the insulating layer 222 and the upper electrode layer 221 can be recessed and filled in the trenches 214 to form the MIM structure 220 in the trenches 214.

In some embodiments, the conductive metal layer 210, the upper electrode layer 221, and the lower electrode layer 223 may be made of the same material. The conductive metal layer 210, the upper electrode layer 221, and the lower electrode layer 223 may be made of titanium nitride (TiN), titanium aluminum (TiAl), titanium aluminum nitride (TiAlN), tantalum nitride (TaN), or tantalum aluminum (TaAl), tantalum aluminum nitride (TaAlN), tantalum aluminum carbide (TaAlC), tantalum carbon nitride (TaCN), aluminum (Al), tungsten (W), nickel (Ni), titanium (Ti), ruthenium (Ru), Cobalt (Co), platinum (Pt), tantalum carbide (TaC), tantalum silicon nitride (TaSiN), copper (Cu), other refractory metals or other suitable metal materials or combinations thereof.

The insulating layer 222 may be a dielectric material including silicon oxide (SiOx), aluminum oxide (AlOx), hafnium oxide: zirconium oxide (HfOx: ZrOx), hafnium oxide: aluminum oxide (HfOx: AlOx), hafnium oxide: oxide Lanthanum (HfOx: LaOx), hafnium oxide: silicon oxide (HfOx: SiOx), hafnium oxide: strontium oxide (HfOx: SrO), hafnium zirconium oxide (HZO) doped with cerium oxide (CeOx), etc.

In one embodiment, each of the upper and lower electrodes 221 and 223 may be a laminated electrode including multiple layers (i.e., a base electrode 202 and a metal layer 204), and the thickness of the upper and lower electrodes 221 and 223 may be about 2 nm to 50 nm. The base electrode 202 and the metal layer 204 have the same property with the base electrode 102 and the metal layer 104 in FIG. 2, and the description will not be repeated here.

As shown in FIG. 9, the base electrode 202 is made of metal nitride, such as titanium nitride (TiN), tungsten nitride (WN), niobium nitride (NbN), molybdenum nitride (MoN), vanadium nitride (VN), cobalt nitride (CoN), chromium nitride (CrN), nickel nitride (Ni₃N) and the like. The metal layer 204 is formed on the base electrode 202. The material of the metal layer 204 includes titanium (Ti), tungsten (W), niobium (Nb), molybdenum (Mo), vanadium (V), cobalt (Co), chromium (Cr), nickel (Ni) or a combination thereof. For example, when titanium nitride (TiN) is selected as the base electrode 202, titanium (Ti) can be used as the metal layer 204 to have good adhesion to the base electrode 202; when tungsten nitride (WN) is selected as the base electrode 202, tungsten (W) can be used as the metal layer 204 to have good adhesion to the base electrode 202, and so on. The metal layer 204 is located between the base electrode 202 and the insulating layer 222.

As shown in FIG. 11, when the insulating layer 222 is formed on the lower electrode layer 223, the metal layer 204 reacts with oxygen to form metal oxide (such as titanium oxide) 206 between the metal layer 204 and the insulating layer 222, instead of forming metal oxynitride (such as TiON), the metal oxide 206 can prevent metal oxynitride (such as TiON) from being generated between the lower electrode layer 223 and the insulating layer 222 to improve reliability of the MIM structure 220.

The present disclosure is directed to a semiconductor device and a manufacturing method thereof. A bottom gate electrode is formed, and the bottom gate electrode has a base electrode and a metal layer disposed on top of the base electrode. When the gate insulating layer is formed on the top of the bottom gate electrode, the metal layer reacts with oxygen to form metal oxide (such as titanium oxide), instead of forming metal oxynitride (such as TiON), the metal oxide can prevent metal oxynitride (such as TiON) from being generated between the base electrode and the gate insulating layer to improve reliability of the bottom gate electrode.

According to some embodiments of the present disclosure, a semiconductor device includes a bottom gate electrode, a gate insulating layer, an active layer, a dielectric layer, a source electrode and a drain electrode. The bottom gate electrode has a base electrode and a metal layer disposed on top of the base electrode. The gate insulating layer is disposed between the bottom gate electrode and the active layer. The dielectric layer is disposed on a side of the active layer. The source electrode and the drain electrode pass through the dielectric layer for electrically connecting to the active layer.

According to some embodiments of the present disclosure, a method for manufacturing a semiconductor device is provided. The manufacturing method includes the following steps. A bottom gate electrode is formed, and the bottom gate electrode has a base electrode and a metal layer disposed on top of the base electrode. A gate insulating layer is formed on the bottom gate electrode. An active layer is formed on the gate insulating layer. A dielectric layer is formed on the active layer, wherein the dielectric layer is partially etched to form at least two vias, and the two vias expose a portion of the active layer. A source electrode and a drain electrode are formed into the two vias respectively for electrically connecting the active layer.

According to some embodiments of the present disclosure, a manufacturing method for a MIM capacitor is provided. The manufacturing method includes the following steps. A conductive metal layer is formed on a substrate. A patterned interlayer dielectric layer is formed on the substrate. The patterned dielectric layer has a trench, and the conductive metal layer is exposed from the bottom of the trench. A metal-insulator-metal (MIM) structure is formed above the patterned interlayer dielectric layer and in the trench. The MIM structure includes an upper electrode layer, an insulating layer and a lower electrode layer. The insulating layer is located on the upper electrode layer and the lower electrode layer, wherein the lower electrode layer covers sidewalls and the bottom of the trench, and the lower electrode layer is electrically connected to the conductive metal layer. In one embodiment, the trench may be a via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a bottom gate electrode having a base electrode and a metal layer disposed on top of the base electrode;
a gate insulating layer;
an active layer, wherein the gate insulating layer is disposed between the bottom gate electrode and the active layer;
a dielectric layer disposed on a side of the active layer;
a source electrode; and
a drain electrode, wherein the source electrode and the drain electrode pass through the dielectric layer for electrically connecting to the active layer.

2. The semiconductor device according to claim 1, wherein the bottom gate electrode further comprises a metal oxide disposed on top of the metal layer.

3. The semiconductor device according to claim 2, wherein the metal oxide comprises a material of the metal layer, and the material contains titanium (Ti), tungsten (W), niobium (Nb), molybdenum (Mo), vanadium (V), cobalt (Co), chromium (Cr), nickel (Ni) or a combination thereof.

4. The semiconductor device according to claim 1, wherein the base electrode comprises a material of titanium nitride (TiN), tungsten nitride (WN), niobium nitride (NbN), molybdenum nitride (MoN), vanadium nitride (VN), cobalt nitride (CoN), chromium nitride (CrN), nickel nitride (Ni₃N) or a combination thereof.

5. The semiconductor device according to claim 1, wherein the active layer is an oxide-semiconductor comprising a material selected from at least one of In, Ga, and Zn.

6. The semiconductor device according to claim 1, wherein the dielectric layer comprises a material of SiOx, HfO₂, Al₂O₃, TiO₂, ZrO₂ or a combination thereof.

7. The semiconductor device according to claim 1, wherein the source electrode and the drain electrode comprise a material of TaN, TiN, Mo, W, Ti or a combination thereof.

8. A method for manufacturing a semiconductor device, comprising:
forming a bottom gate electrode, the bottom gate electrode having a base electrode and a metal layer disposed on top of the base electrode;
forming a gate insulating layer on the bottom gate electrode;
forming an active layer on the gate insulating layer;
forming a dielectric layer on the active layer, wherein the dielectric layer is partially etched to form at least two vias, and the two vias expose a portion of the active layer; and
forming a source electrode and a drain electrode into the two vias respectively for electrically connecting the active layer.

9. The method according to claim 8, wherein forming the bottom gate electrode comprises forming a metal oxide on top of the metal layer when the metal layer reacts with oxygen.

10. The method according to claim 9, wherein the metal oxide comprises a material of the metal layer, the material contains titanium (Ti), tungsten (W), niobium (Nb), molybdenum (Mo), vanadium (V), cobalt (Co), chromium (Cr), nickel (Ni) or a combination thereof.

11. The method according to claim 8, wherein the base electrode comprises a material of titanium nitride (TiN), tungsten nitride (WN), niobium nitride (NbN), molybdenum nitride (MoN), vanadium nitride (VN), cobalt nitride (CoN), chromium nitride (CrN), nickel nitride (Ni₃N) or a combination thereof.

12. The method according to claim 8, wherein the active layer is a metal oxynitride semiconductor comprising a material selected from at least one of In, Ga, and Zn.

13. The method according to claim 8, wherein the dielectric layer comprises a material of SiOx, HfO₂, Al₂O₃, TiO₂, ZrO₂ or a combination thereof.

14. The method according to claim 8, wherein the source electrode and the drain electrode comprise a material of TaN, TiN, Mo, W, Ti or a combination thereof.

15. A method for manufacturing a metal-insulator-metal (MIM) capacitor, comprising:
forming a conductive metal layer on a substrate;
forming a patterned interlayer dielectric layer on the substrate, the patterned interlayer dielectric layer having a trench or a via, and the conductive metal layer being exposed from a bottom of the trench or the via; and
forming a MIM structure on the patterned interlayer dielectric layer and in the trench or the via, the MIM structure comprising an upper electrode layer, an insulating layer and a lower electrode layer, the insulating layer being located between the upper electrode layer and the lower electrode layer, wherein the lower electrode layer covers sidewalls and the bottom of the trench or the via, and the lower electrode layer is electrically connected to the conductive metal layer.

16. The method according to claim 15, wherein the lower electrode layer comprises a base electrode and a metal layer disposed on top of the base electrode, wherein the metal layer is located between the base electrode and the insulating layer.

17. The method according to claim 16, wherein forming the lower electrode layer further comprises forming a metal oxide on top of the metal layer when the metal layer reacts with oxygen.

18. The method according to claim 17, wherein the metal oxide comprises a material of the metal layer, the material contains titanium (Ti), tungsten (W), niobium (Nb), molybdenum (Mo), vanadium (V), cobalt (Co), chromium (Cr), nickel (Ni) or a combination thereof.

19. The method according to claim 16, wherein the base electrode comprises a material of titanium nitride (TiN), tungsten nitride (WN), niobium nitride (NbN), molybdenum nitride (MoN), vanadium nitride (VN), cobalt nitride (CoN), chromium nitride (CrN), nickel nitride (Ni₃N) or a combination thereof.

20. The method according to claim 16, wherein the MIM structure is a three-dimensional MIM structure.
